(19) United States
(12) Patent Application Publication
(10) Pub. No.: US 2025/0014937 A1
(43) Pub. Date: Jan. 9, 2025

(54) METHOD FOR MANUFACTURING SEMICONDUCTOR DEVICE

(71) Applicant: Resonac Corporation, Minato-ku, Tokyo (JP)

(72) Inventors: Motoo AOYAMA, Minato-ku, Tokyo (JP); Kazutaka HONDA, Minato-ku, Tokyo (JP); Masataka NISHIDA, Minato-ku, Tokyo (JP)

(21) Appl. No.: 18/695,369

(22) PCT Filed: Sep. 27, 2021
(86) PCT No.: PCT/JP2021/035418

§ 371 Date: Sep. 20, 2024

(51) Int. Cl. H01L 21/683

(52) U.S. Cl. CPC H01L 21/6836; H01L 2221/68354; H01L 2221/68363

(57) ABSTRACT

A method for manufacturing a semiconductor device includes a tape expanding step of stretching an expansion tape while heating to expand an interval between a plurality of semiconductor chips fixed onto the expansion tape at an expansion rate in a range A per one expansion, a transferring step of transferring the plurality of semiconductor chips to an expansion tape, and repeating the tape expanding step and the transferring step. In a stress-strain curve according to a tensile test of the expansion tape, an elongation range B in which an absolute value of a difference between a MD tensile stress and a TD tensile stress is 2.8 MPa or less overlaps with a part of the range A. The tape expanding step includes expanding the interval by using an elongation value selected from an overlapping range between the range A and the range B as the expansion rate per one expansion.

### TECHNICAL FIELD

The present disclosure relates to a method for manufacturing a semiconductor device.

### BACKGROUND ART

Recently, the number of pins and the density of a semiconductor have increased and the pitch of wiring has decreased in accordance with the downsizing, higher functionality, and higher integration of a semiconductor device. Therefore, a weak layer such as a low-K layer has been applied in order for the miniaturization or a lower dielectric constant of the pin or the wiring, and accordingly, a technology for high reliability has been required.

Against such a background, a wafer level package (WLP) technology enabling high reliability, high productivity, and the like has progressed. The WLP technology is characterized by performing assembly in a wafer state, and singulating the wafer with dicing in the final process. The WLP technology is a technology enabling high productivity and high reliability since the assembly (sealing) is collectively performed at a wafer level. In the WLP technology, a redistribution layer is formed in which a redistribution pattern is formed of polyimide, copper wiring, or the like on an insulating film of a circuit surface of a semiconductor chip, and a metal pad, a solder ball, or the like is mounted on the redistribution to configure a bump for a connection terminal.

WLP includes a semiconductor package in which a semiconductor chip is comparable with a package area, such as a wafer level chip scale package (WLCSP) and a fan in wafer level package (FI-WLP), and a semiconductor package in which a package area is larger than a semiconductor chip area and a terminal can be extended to the outside the chip, such as a fan out wafer level package (FO-WLP). In such a semiconductor package, downsizing and thinning have rapidly progressed, and in order to ensure the reliability, the sealing is performed at the wafer level, and the formation of the redistribution layer, the singulation for each package, and the like are performed after the periphery of the semiconductor chip is protected.

In such a semiconductor package, as described above, the sealing is performed at the wafer level, and the subsequent handling such as secondary mounting is performed to ensure the reliability. In addition, even in the field of mounting a monofunctional semiconductor such as a discrete semiconductor, the sealing is performed at the wafer level in order to reduce a crack on the semiconductor chip when handling or a stress on the periphery of the pad. Next, the periphery of the semiconductor chip is protected, and then, the singulation is performed for each package, and the next step (such as an SMT process) is performed. The discrete semiconductor is often smaller than a system LCI, and in order to protect the semiconductor chip at a higher level, the sealing of five or six surfaces of the semiconductor chip is particularly required to be implemented.

In order to seal the lateral surface of such a semiconductor chip, it is necessary to extend an interval between the semiconductor chips after the semiconductor chip is prepared by singulating the wafer. For example, in Patent Literature 1, a method for fixing a plurality of chips onto an expansion tape, stretching the expansion tape to extend an interval between the semiconductor chips, and then, peeling off the expansion tape from the semiconductor chip, and an expansion tape that can be used in the method described above are disclosed.

### CITATION LIST

### Patent Literature

Patent Literature 1: WO 2018/216621 A1

### SUMMARY OF INVENTION

### Technical Problem

However, according to the consideration of the present inventors, it has been found that when stretching the expansion tape of the related art, a phenomenon that the semiconductor chip fixed onto the expansion tape is moved to a position different from a position where the semiconductor chip is assumed to be positioned after the stretching, that is, the position aberration of the semiconductor chip may occur. In a case where the position aberration of the semiconductor chip is large, for example, there is a concern that the semiconductor chip may be damaged in the dicing after the collective sealing, or a pickup failure occurs and the productivity decreases.

Therefore, an object of the present disclosure is to provide a method for manufacturing a semiconductor device in which the position aberration of a semiconductor chip is sufficiently suppressed when expanding an interval between singulated semiconductor chips.

### Solution to Problem

One aspect of the present disclosure relates to a method for manufacturing a semiconductor device having a semiconductor chip. The method for manufacturing a semiconductor device includes a tape expanding step of stretching a transferring expansion tape while heating to expand an interval between a plurality of semiconductor chips fixed onto the transferring expansion tape at an expansion rate in a range of greater than 100% and less than 300% per one expansion, a transferring step of transferring the plurality of semiconductor chips to a transferred expansion tape such that a surface of the semiconductor chip on a side opposite to a surface fixed onto the transferring expansion tape is fixed, and a repeating step of repeating the tape expanding step and the transferring step in this order by using the transferred expansion tape to which the plurality of semiconductor chips are transferred as the transferring expansion tape.

In a stress-strain curve obtained by a tensile test in an MD direction and a TD direction under a heating temperature in the tape expanding step of the transferring expansion tape and the transferred expansion tape, when a tensile stress in the MD direction and a tensile stress in the TD direction are set as fa (MPa) and fb (MPa), respectively, an elongation range in which an absolute value of a difference between fa and fb is 2.8 MPa or less overlaps with at least a part of the range of greater than 100% and less than 300%.

Note that, in this specification, MD in the MD direction is an abbreviation for a machine direction, and the MD direction indicates a direction parallel to a longitudinal direction in a film that provides a base material film configuring the transferring expansion tape and the transferred expansion tape. In addition, TD in the TD direction is an abbreviation for a transverse direction, and the TD direction indicates a direction orthogonal to the MD direction.

The tape expanding step is a step of expanding the interval between the plurality of semiconductor chips by using an elongation value selected from the elongation range of greater than 100% and less than 300%, in which the absolute value of the difference between fa and fb is 2.8 MPa or less, as the expansion rate per one expansion.

According to the consideration of the present inventors, it has been found that when expanding the expansion tape of the related art in a large range per one expansion (for example, a range of 300% or more per one expansion), there is a tendency that the position aberration of the semiconductor chip increases. In contrast, according to the method for manufacturing a semiconductor device of the present disclosure characterized by using a predetermined expansion tape to select the expansion rate per one expansion from the properties of the predetermined expansion tape, expanding the interval between the plurality of semiconductor chips on the basis of the selected expansion rate, and repeating the tape expanding step and the transferring step in this order (preferably repeating the tape expanding step and the transferring step a plurality of times until a desired range is attained), it is possible to gradually expand the interval between the semiconductor chips, and even when expanding the interval between the singulated semiconductor chips to a target range of, for example, 300% or more with respect to the initial interval between the semiconductor chips, it is possible to sufficiently suppress the position aberration of the semiconductor chip.

### Advantageous Effects of Invention

According to the present disclosure, the method for manufacturing a semiconductor device is provided in which the position aberration of the semiconductor chip is sufficiently suppressed when expanding the interval between the singulated semiconductor chips.

### BRIEF DESCRIPTION OF DRAWINGS

FIG. 1 is a schematic sectional view for illustrating one embodiment of a method for manufacturing a semiconductor device, in which FIG. 1A, FIG. 1B, FIG. 1C, and FIG. 1D are diagrams illustrating each step.

FIG. 2 is a schematic sectional view for illustrating one embodiment of the method for manufacturing a semiconductor device, in which FIG. 2A, FIG. 2B, FIG. 2C, and FIG. 2D are diagrams illustrating each step.

FIG. 3 is a schematic sectional view for illustrating one embodiment of the method for manufacturing a semiconductor device, in which FIG. 3A and FIG. 3B are diagrams illustrating each step.

FIG. 4 is a graph of a stress-strain curve obtained by a tensile test in an MD direction and a TD direction of a base material film (an expansion tape of Manufacturing Example 1).

### DESCRIPTION OF EMBODIMENTS

Hereinafter, this embodiment will be described in detail with reference to the drawings. Here, the present disclosure is not limited to the following embodiment. In the following embodiment, the constituents (also including steps or the like) are not essential unless otherwise specified. The same reference numerals will be applied to the same or corresponding parts, and the repeated description will be omitted. In addition, a positional relationship such as the top, bottom, right, and left is based on a positional relationship illustrated in the drawings, unless otherwise specified. The size of the constituents in each of the drawings is conceptual, and a relative size relationship between the constituents is not limited to that illustrated in each of the drawings.

The same applies to numerical values and the ranges thereof in the present disclosure, but does not limit the present disclosure. In this specification, a numerical range represented by using “to” indicates a range including numerical values described before and after “to” as the minimum value and the maximum value, respectively. In numerical ranges described in stages in this specification, the upper limit value or the lower limit value of a numerical range in a certain stage may be replaced with the upper limit value or the lower limit value of a numerical range in the other stage. In addition, in the numerical range described in this specification, the upper limit value or the lower limit value of the numerical range may be replaced with values described in Examples.

In this specification, the term “layer” includes not only a structure in which a layer is formed on the entire surface but also a structure in which a layer is formed on a part of the surface when observed as a plan view. In addition, in this specification, the term “step” includes not only an independent step but also a step that is not explicitly distinguishable from other steps insofar as a desired function of the step is attained.

In this specification, (meth)acrylate indicates acrylate or methacrylate corresponding thereto. The same applies to other similar expressions such as a (meth)acrylic copolymer.

In each component and material exemplified in this specification, only one type may be used alone, or two or more types thereof may be used together, unless otherwise specified.

### [Method for Manufacturing Semiconductor Device]

A method for manufacturing a semiconductor device of one embodiment relates to a method for manufacturing a semiconductor device having a semiconductor chip. The method for manufacturing a semiconductor device includes a tape expanding step of stretching a transferring expansion tape while heating to expand an interval between a plurality of semiconductor chips fixed onto the transferring expansion tape at an expansion rate in a range of greater than 100% and less than 300% per one expansion, a transferring step of transferring the plurality of semiconductor chips to a transferred expansion tape such that a surface of the semiconductor chip on a side opposite to a surface fixed onto the transferring expansion tape is fixed, and a repeating step of repeating the tape expanding step and the transferring step in this order by using the transferred expansion tape to which the plurality of semiconductor chips are transferred as the transferring expansion tape.

In a stress-strain curve obtained by a tensile test in an MD direction and a TD direction under a heating temperature in the tape expanding step of the transferring expansion tape and the transferred expansion tape, when a tensile stress in the MD direction and a tensile stress in the TD direction are set as fa (MPa) and fb (MPa), respectively, an elongation range in which an absolute value of a difference between fa and fb is 2.8 MPa or less overlaps with at least a part of the range of greater than 100% and less than 300%.

In the method for manufacturing a semiconductor device of this embodiment, after the tape expanding step using the expansion tape (the transferring expansion tape), transfer to another expansion tape (the transferred expansion tape) is performed, and tape expanding step and the transferring step are repeated in this order by using another expansion tape until final transfer to a carrier is performed.

The method for manufacturing a semiconductor device, for example, may further include the following steps.
A preparing step of preparing a laminated body including the plurality of semiconductor chips fixed onto the transferring expansion tape and the transferring expansion tape
A tension retaining step of retaining the tension of the stretched transferring expansion tape
A carrier transferring step of transferring the plurality of semiconductor chips to the carrier after the repeating step

The transferring expansion tape and the transferred expansion tape have a base material film, and an adhesive layer provided on the base material film (hereinafter, the transferring expansion tape and the transferred expansion tape may be collectively referred to as an “expansion tape” for convenience). The adhesive layer, for example, may include a pressure-sensitive adhesive agent, or may include an ultraviolet-curable adhesive agent. The adhesive layer may consist of the pressure-sensitive adhesive agent, or may consist of the ultraviolet-curable adhesive agent. In a case where the adhesive layer includes the ultraviolet-curable adhesive agent, the method for manufacturing a semiconductor device may further include an ultraviolet irradiating step of irradiating the expansion tape with an ultraviolet ray. The ultraviolet irradiating step may be provided before and after any step. The ultraviolet irradiating step depends on the properties of the ultraviolet-curable adhesive agent, but may be provided between the preparing step and the tape expanding step, or may be provided between the tension retaining step and the transferring step.

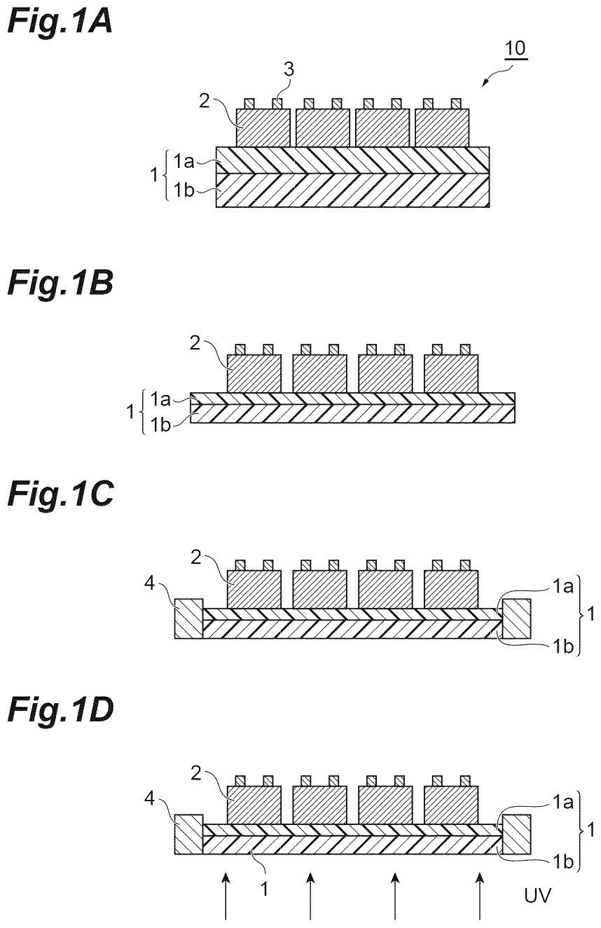

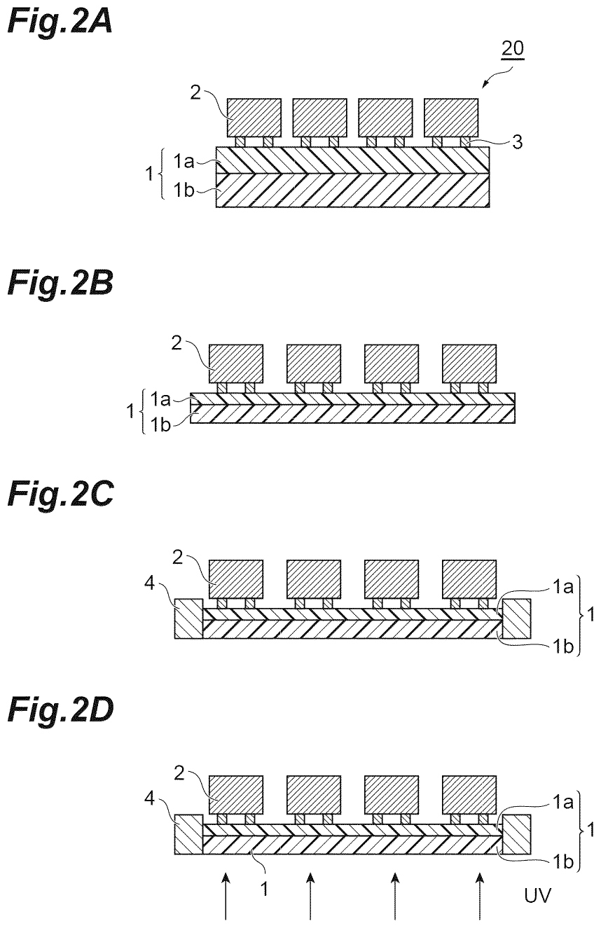

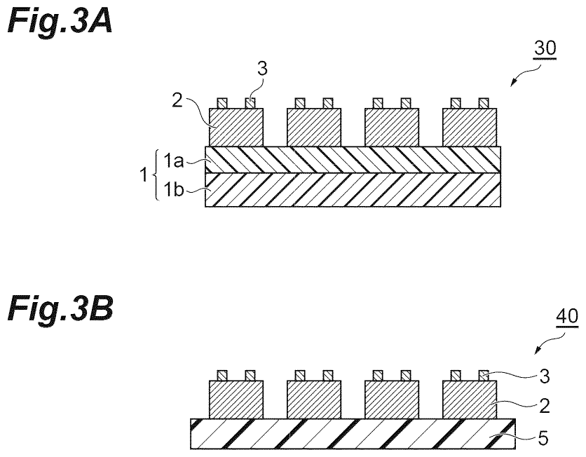

FIG. 1, FIG. 2, and FIG. 3 are schematic sectional views for illustrating one embodiment of the method for manufacturing a semiconductor device. Hereinafter, each step will be described.

### (Preparing Step)

In the preparing step, a laminated body 10 including an expansion tape 1, and a plurality of semiconductor chips 2 fixed onto the expansion tape 1 is prepared. The expansion tape 1 includes a base material film 1b, and an adhesive layer 1a provided on the base material film 1b, and the adhesive layer 1a is in contact with the semiconductor chip 2. In addition, the semiconductor chip 2 may have a circuit surface on which a pad (a circuit) 3 is provided. In FIG. 1, an aspect is illustrated in which the surface of the semiconductor chip 2 on a side opposite to the circuit surface is fixed to the expansion tape 1 (FIG. 1A), but the circuit surface of the semiconductor chip 2 may be fixed to the expansion tape 1.

The laminated body 10, for example, can be prepared by laminating a semiconductor wafer on a dicing tape or the like, and then, performing dicing with a blade or laser to prepare a plurality of singulated semiconductor chips, and transferring the semiconductor chips to the expansion tape 1.

The dicing may be dicing using a blade, or may be stealth dicing in which a weak layer is formed and expanded with laser. In addition, from the viewpoint of improving productivity, the laminated body may be prepared by directly laminating the semiconductor wafer on the expansion tape 1 without performing the transfer process described above, and dicing the semiconductor wafer using the method described above.

From the viewpoint of improving the productivity and reducing a cost, it is preferable that the initial interval between the semiconductor chips 2 (the interval between the semiconductor chips before the tape expanding step) is narrow, and for example, the initial interval is 100 μm or less, preferably 80 μm or less, and more preferably 60 μm or less. In the cutting of the semiconductor wafer using dicing, since the semiconductor wafer is wasted in a case where the initial interval between the semiconductor chips 2 is wide, it is preferable that the initial interval is narrow as described above from the viewpoint of reducing the cost. When expanding the interval between the semiconductor chips 2, the initial interval between the semiconductor chips 2 is preferably 10 μm or more from the viewpoint of avoiding a stress on the semiconductor chip 2. In a case where the initial interval between the semiconductor chips 2 is less than 10 μm, there is a tendency that an expansion tape region between the plurality of semiconductor chips 2 is small and difficult to expand.

The size of the semiconductor chip 2 is not particularly limited, and for example, is 25 mm² (5 mm×5 mm) or less, and preferably 9 mm² (3 mm×3 mm) or less.

The type of pad 3 on the circuit surface of the semiconductor chip 2 is not particularly limited insofar as the pad can be formed on the circuit surface of the semiconductor chip 2, and may be a bump (a bump electrode) such as a copper bump and a solder bump, or may be a comparatively flat metal pad such as a Ni/Au-plated pad.

The semiconductor chip 2 may be provided with a resin part for protecting the semiconductor chip from the outside, an external terminal for electrically connecting a semiconductor element, and the like.

In this specification, the term “semiconductor chip” includes a semiconductor package provided with a resin part for protecting the semiconductor package from the outside, an external terminal for electrically connecting a semiconductor element, and the like. In a case where the semiconductor package is used in the preparing step, for example, the laminated body can be prepared by laminating the semiconductor package prepared at a substrate level on the dicing tape or the like, and then, performing the dicing with the blade or the laser to obtain the plurality of singulated semiconductor chips, and then, transferring the semiconductor chips to the expansion tape.

### (Tape Expanding Step)

In the tape expanding step, by stretching the expansion tape 1 while heating, the interval between the plurality of semiconductor chips 2 fixed onto the expansion tape 1 is expanded at the expansion rate in the range of greater than 100% and less than 300% per one expansion (FIG. 1B). Here, the tape expanding step is a step of expanding the interval between the plurality of semiconductor chips 2 by using an elongation value selected from the elongation range of greater than 100% and less than 300%, in which the absolute value of the difference between fa and fb is 2.8 MPa or less, as the expansion rate per one expansion.

Examples of a method for stretching the expansion tape include a thrust method, a tensile method, and the like. In the thrust method, the expansion tape is fixed, and then, the expansion tape is expanded by raising a stage with a predetermined shape. In the tensile method, the expansion tape is fixed, and then, the expansion tape is expanded by pulling the expansion tape in a predetermined direction parallel to the surface of the provided expansion tape. The thrust method is preferable from the viewpoint that the interval between the semiconductor chips is evenly expanded and the required (occupied) device area is small and compact.

A stretching condition can be suitably set in accordance with the properties of the expansion tape. For example, a thrust amount (a tensile amount) in a case where the thrust method is adopted is preferably 10 to 150 mm, and more preferably 10 to 120 mm. In a case where the thrust amount is 10 mm or more, the interval between the plurality of semiconductor chips is easily expanded, and in a case where the thrust amount is 150 mm or less, the shattering or the position aberration of the semiconductor chip is less likely to occur.

A heating temperature in the tape expanding step (a temperature during stretching) can be suitably set in accordance with the properties of the expansion tape. The temperature during stretching, for example, may be 25 to 200° C., or may be 25 to 150° C. or 30 to 100° C. In a case where the temperature during stretching is 25° C.′ or higher, the expansion tape is easily stretched, and in a case where the temperature during stretching is 200° C. or lower, it is possible to prevent the position aberration of the semiconductor chip (peeling between the expansion tape and the semiconductor chip) due to strain or sagging caused by the thermal expansion or low elasticity of the expansion tape, the shattering of the semiconductor chip, and the like at a higher level. The heating temperature in the tape expanding step, for example, can be 50° C.

A thrust rate can also be suitably set in accordance with the properties of the expansion tape. The thrust rate, for example, may be 0.1 to 500 mm/second, or may be 0.1 to 300 mm/second or 0.1 to 200 mm/second. In a case where the thrust rate is 0.1 mm/second or more, it is possible to further improve the productivity. In a case where the thrust rate is 500 mm/second or less, the peeling between the semiconductor chip and the expansion tape is less likely to occur.

In order to ensure the required space for providing a redistribution pattern and a pad for a connection terminal outside the region of the semiconductor chip, the interval between the plurality of semiconductor chips after the tape expanding step is greater than 100% and less than 300% with respect to the interval between the plurality of semiconductor chips before the tape expanding step (the initial interval between the semiconductor chips). By using a predetermined expansion tape described below and expanding the predetermined expansion tape at a predetermined expansion rate, it is possible to sufficiently suppress the position aberration of the semiconductor chip. The interval between the plurality of semiconductor chips after the tape expanding step, for example, may be 105% or more or 110% or more, and may be 295% or less or 290% or less, with respect to the interval between the plurality of semiconductor chips before the tape expanding step (the initial interval between the semiconductor chips).

The tape expanding step is a step of expanding the interval between the plurality of semiconductor chips by using the elongation value selected from the elongation range of greater than 100% and less than 300%, in which the absolute value of the difference between fa and fb is 2.8 MPa or less, as the expansion rate per one expansion. According to the consideration of the present inventors, it has been found that the interval between the semiconductor chips can be gradually expanded by using the predetermined expansion tape to select the expansion rate per one expansion from the properties of the predetermined expansion tape, and expanding the interval between the plurality of semiconductor chips on the basis of the selected expansion rate, and even in a case where the interval between the singulated semiconductor chips is expanded to a target range of, for example, 300% or more with respect to the initial interval between the semiconductor chips, the position aberration of the semiconductor chip can be sufficiently suppressed.

For example, in the expansion tape, when assuming that the elongation range in which the absolute value of the difference between fa and fb is 2.8 MPa or less is in the following ranges a to d, such elongation ranges overlap with at least a part of the range of greater than 100% and less than 300%.
Range a: 50% or more and 200% or less
Range b: 200% or more and 400% or less
Range c: 150% or more and 250% or less
Range d: 50% or more and 400% or less

The tape expanding step is a step of expanding the interval between the plurality of semiconductor chips by using the elongation value selected from the elongation range of greater than 100% and less than 300%, in which the absolute value of the difference between fa and fb is 2.8 MPa or less, as the expansion rate per one expansion.

Hereinafter, a method for selecting the expansion rate per one expansion in the tape expanding step will be described in detail by using the expansion tape of which the elongation range in which the absolute value of the difference between fa and fb is 2.8 MPa or less is in the ranges a to d described above, as an example. In such an expansion tape, an overlapping range between the ranges a to d described above and the elongation range of greater than 100% and less than 300% is a range for selecting the expansion rate per one expansion. Such an overlapping range is the following ranges for each of the ranges a to d described above.
Range a: greater than 100% and 200% or less
Range b: 200% or more and less than 300%
Range c: 150% or more and 250% or less
Range d: greater than 100% and less than 300%

For example, in the case of using the expansion tape of which the elongation range in which the absolute value of the difference between fa and fb is 2.8 MPa or less is in the range a described above, the expansion rate per one expansion in the tape expanding step is arbitrarily selected from the range of greater than 100% and 200% or less. Similarly, in the case of using the expansion tape in the range b, the expansion rate per one expansion in the tape expanding step is arbitrarily selected from the range of 200% or more and less than 300%. In the case of using the expansion tape in the range c, the expansion rate per one expansion in the tape expanding step is arbitrarily selected from the range of 150% or more and 250% or less. In the case of using the expansion tape in the range d, the expansion rate per one expansion in the tape expanding step is arbitrarily selected from the range of greater than 100% and less than 300%.

In one embodiment, the maximum value of the elongation range in which the absolute value of the difference between fa and fb is 2.8 MPa or less may be 300% or more. In a case where the maximum value of the elongation range in which the absolute value of the difference between fa and fb is 2.8 MPa or less is 300% or more, the tape expanding step can be a step of expanding the interval between the plurality of semiconductor chips by using the elongation range of greater than 100% and less than 300% as the expansion rate per one expansion.

The position aberration in the tape expanding step, for example, is defined as follows.
1. Before and after the tape expanding step, the coordinate position of the center semiconductor chip is measured, and then, the coordinate position of any semiconductor chip is measured.
2. It is assumed that the expansion is performed at a predetermined expansion rate, and the assumed ideal coordinate position of the semiconductor chip at this time is determined.
3. The average value of a difference between the coordinate position of 1 and the coordinate position of 2 is calculated and defined as the position aberration.

More specifically, the position aberration in the tape expanding step can be obtained by a method described in Examples. In a case where the expansion is performed to the target range of, for example, 300% or more with respect to the initial interval between the semiconductor chips, it is preferable that the position aberration in the tape expanding step is suppressed to 250 μm or less.

### (Tension Retaining Step)

In the tension retaining step, the stretched expansion tape 1 is fixed by using a fixing jig 4 to retain the tension of the expansion tape 1 (FIG. 1C).

In the tension retaining step, in order to prevent the stretched expansion tape from returning to the original state, the tension of the expansion tape is retained.

A method for retaining the tension of the expansion tape is not particularly limited insofar as the tension is retained and the interval between the semiconductor chips does not return to the original state. Examples of the method include a fixing method using a fixing jig such as a grip ring (manufactured by Technovision, Inc.), a method for retaining a tension by heating and shrinking (heat shrink) the outer circumferential portion of an expansion tape, and the like.

### (Ultraviolet Irradiating Step)

The method for manufacturing a semiconductor device, as necessary, may include the ultraviolet irradiating step. In the ultraviolet irradiating step that can be provided, as necessary, between the tension retaining step and the transferring step, the stretched expansion tape 1 is irradiated with an ultraviolet ray to decrease the adhesive force (the peeling strength) of the expansion tape 1 to the semiconductor chip 2 (FIG. 1D). The ultraviolet irradiating step may be provided between the preparing step and the tape expanding step, but not between the tension retaining step and the transferring step.

In the ultraviolet irradiating step, by irradiating the stretched expansion tape with the ultraviolet ray, the adhesive force of the expansion tape to the semiconductor chip is decreased. In this embodiment, it is preferable to use an ultraviolet ray at a wavelength of 200 to 400 nm, and as an irradiation condition thereof, it is preferable that the irradiation is performed at an illumination of 30 to 240 mW/cm² and an irradiation amount of 200 to 500 mJ/cm².

### (Transferring Step)

In the transferring step, the plurality of semiconductor chips 2 are transferred to the expansion tape 1 such that the surface of the semiconductor chip on a side opposite to the surface fixed onto the expansion tape 1 is fixed (FIG. 2A). The expansion tape 1 has the base material film 1b, and the adhesive layer 1a provided on the base material film 1b, and the adhesive layer 1a is in contact with the circuit surface of the semiconductor chip 2. In the preparing step, in a case where the circuit surface of the semiconductor chip 2 is fixed to the expansion tape 1, the adhesive layer 1a of the expansion tape 1 is in contact with the surface of the semiconductor chip 2 on a side opposite to the circuit surface. As described above, it is possible to obtain a laminated body 20 including the expansion tape 1 (the transferred expansion tape), and the plurality of semiconductor chips 2 fixed onto the expansion tape 1 (the transferred expansion tape).

A laminating method is not particularly limited, but a roll laminator, a diaphragm laminator, a vacuum roll laminator, and a vacuum diaphragm laminator can be adopted.

A laminating condition may be suitably set in accordance with the physical properties and the properties of the expansion tape and the semiconductor chip. For example, in the case of the roll laminator, the laminating condition may be 25 to 200° C., preferably 25 to 150° C., and more preferably 25 to 100° C. In a case where the laminating condition is 25° C. or higher, it is easy to transfer the semiconductor chip 2 to the expansion tape 1, and in a case where the laminating condition is 200° C. or lower, it is possible to prevent the position aberration of the semiconductor chip 2 (the peeling between the expansion tape 1 and the semiconductor chip 2) due to the strain or the sagging based on the thermal expansion, the low elasticity, and the like of the expansion tape 1, the shattering of the semiconductor chip 2, and the like at a high level. In the case of the diaphragm laminator, the temperature condition is the same as that of the roll laminator described above. A compression time may be 5 to 300 seconds, and is preferably 5 to 200 seconds, and more preferably 5 to 100 seconds. In a case where the compression time is 5 seconds or longer, it is easy to transfer the semiconductor chip 2 to the expansion tape 1, and in a case where the compression time is 300 seconds or shorter, it is possible to improve the productivity. A compression pressure may be 0.1 to 3 MPa, and is preferably 0.1 to 2 MPa, and more preferably 0.1 to 1 MPa. In a case where the compression pressure is 0.1 MPa or more, it is easy to transfer the semiconductor chip 2 to the expansion tape 1, and in a case where the compression pressure is 3 MPa or less, a damage to the semiconductor chip 2 is reduced.

### (Repeating Step)

In the repeating step, the tape expanding step and the transferring step are repeated in this order by using the expansion tape 1 (the transferred expansion tape) to which the plurality of semiconductor chips 2 are transferred as the transferring expansion tape (FIG. 2B, FIG. 2C, and FIG. 2D). The repeating step can be a step of transferring the plurality of semiconductor chips 2 to the expansion tape 1 (the transferred expansion tape) or a carrier 5 (FIG. 3A and FIG. 3B). In a case where the plurality of semiconductor chips 2 are transferred to the expansion tape 1, a laminated body 30 including the expansion tape 1, and the plurality of semiconductor chips 2 fixed onto the expansion tape 1 is obtained (FIG. 3A). In the repeating step, the tape expanding step and the transferring step may be implemented in this order a plurality of times by using a plurality of expansion tapes 1 until the final transfer to the carrier is performed. In the repeating step, the tape expanding step may be implemented a total of 2 or more times, preferably 3 or more times, more preferably 4 or more times, and even more preferably 5 or more times.

### (Carrier Transferring Step)

In the carrier transferring step, the plurality of semiconductor chips 2 are transferred to (laminated on) the carrier 5 from the expansion tape 1, after the repeating step. Finally, it is possible to obtain a semiconductor device 40 by peeling off the expansion tape 1 from the semiconductor chip 2 (FIG. 3B).

The laminating method may be suitably set in accordance with the physical properties and the properties of the expansion tape 1, the semiconductor chip 2, and the carrier 5. The laminating method and the laminating condition of the carrier transferring step may be the same as the laminating method and the laminating condition of the transferring step.

Next, materials used in each step will be described.

### [Expansion Tape and Method for Manufacturing Expansion Tape]

In the stress-strain curve obtained by the tensile test in the MD direction and the TD direction under the heating temperature in the tape expanding step of the expansion tape (the transferring expansion tape and the transferred expansion tape), when the tensile stress in the MD direction and the tensile stress in the TD direction are set as fa (MPa) and fb (MPa), respectively, the elongation range in which the absolute value of the difference between fa and fb is 2.8 MPa or less overlaps with at least a part of the range of greater than 100% and less than 300%. The lower limit of the absolute value of the difference between fa and fb, for example, can be 0.1 MPa or more.

Note that, the tensile test in the MD direction and the TD direction under the heating temperature in the tape expanding step of the expansion tape can be performed with a commercially available precision universal tester by using two evaluation samples obtained by cutting out the expansion tape to have a width of 20 mm and a length of 50 mm in each of the MD direction and the TD direction, and stretching each of the evaluation samples from 0 to 400% at a distance between chucks of 50 mm and a tensile rate of 1 mm/s, and accordingly, the stress-strain curve can be obtained. The heating temperature in the tape expanding step is a stage temperature when expanding the expansion tape, and indicates a temperature that is maximized in heating. The heating temperature in the tape expanding step, for example, can be 50° C.

The expansion tape has the base material film, and the adhesive layer provided on the base material film. The tensile test in the MI direction and the TD direction under the heating temperature in the tape expanding step of the expansion tape greatly depends on the properties of the base material film. Therefore, the tensile test in the MD direction and the TD direction under the heating temperature in the tape expanding step is performed with respect to the base material film (the expansion tape not having the adhesive layer), and a stress-strain curve obtained as described above can be regarded as the stress-strain curve obtained by the tensile test in the MD direction and the TD direction of the expansion tape.

By using the predetermined expansion tape to select the expansion rate per one expansion in a narrow range (greater than 100% and less than 300%) from the properties of the predetermined expansion tape, and expanding the interval between the plurality of semiconductor chips on the basis of the selected expansion rate, it is possible to sufficiently suppress the position aberration of the semiconductor chip.

The transferring expansion tape and the transferred expansion tape, which are used as the expansion tape, may be identical to each other, or may be different from each other. In a case where the transferring expansion tape and the transferred expansion tape are identical to each other, an excellent efficiency is attained since the same expansion tape can be used. In the repeating step, in a case where the tape expanding step is implemented a total of 2 or more times, an expansion tape to be used may be identical to or different from the transferring expansion tape and the transferred expansion tape described above. Here, in a case where the expansion tape to be used is identical to the transferring expansion tape and the transferred expansion tape, an excellent efficiency is attained since the same expansion tape can be used.

### (Base Material Film)

The base material film can be used without any particular limitation insofar as a condition that the elongation range in which the absolute value of the difference between fa and fb is 2.8 MPa or less overlaps with at least a part of the range of greater than 100% and less than 300% is satisfied. Examples of the base material film include various plastic films such as a polyester-based film such as a polyethylene terephthalate film; a polyolefin-based film of a homopolymer of «-olefin and a copolymer thereof, an ionomer of such a homopolymer or copolymer, and the like, such as a polytetrafluoroethylene film, a polyethylene film, a polypropylene film, a polymethyl pentene film, a polyvinyl acetate film, and poly-4-methyl pentene-1; a polyvinyl chloride film; a polyimide film; and a urethane resin film. The base material film is not limited to a single-layer film, and may be a multi-layer film obtained by combining two or more types of plastic films or a multi-layer film obtained by combining two or more plastic films of the same type.

The base material film is preferably a polyolefin-based film or a urethane resin film from the viewpoint of a tensile stress and stretchability. The base material film, as necessary, may contain various additives such as an antiblocking agent.

The thickness of the base material film is preferably 50 to 500 μm. In a case where the thickness of the base material film is 50 μm or more, there is a tendency that the stretchability is improved. In a case where the thickness of the base material film is 500 μm or less, there is a tendency that it is possible to suppress a problem that the strain is likely to occur or handleability decreases.

The thickness of the base material film is suitably selected in a range where workability is not impaired. However, in a case where a high-energy ray (in particular, an ultraviolet ray)-curable adhesive agent is used as the adhesive agent configuring the adhesive layer, it is necessary to set a thickness that does not inhibit the transmission of the high-energy ray. From such a viewpoint and from the viewpoint of the tensile stress, the thickness of the base material film may be generally 10 to 500 μm, and is preferably 50 to 400 μm, and more preferably 70 to 300 μm.

In a case where the base material film is the multi-layer film, it is preferable that the thickness of the entire base material film is adjusted to be in the range described above. In order to improve adhesion to the adhesive layer, the base material film, as necessary, may be chemically or physically subjected to a surface treatment. Examples of the surface treatment include a corona treatment, a chromic acid treatment, ozone exposure, flame exposure, high-voltage electric shock exposure, an ionization radiation treatment, and the like.

### (Adhesive Layer)

The adhesive layer is not particularly limited insofar as the adhesive force can be controlled. The adhesive layer, for example, may contain the pressure-sensitive adhesive agent, or may contain the ultraviolet-curable adhesive agent, but may contain the ultraviolet-curable adhesive agent since the adhesive force is easily adjusted by ultraviolet irradiation. It is preferable that the ultraviolet-curable adhesive agent configuring such an adhesive layer contains a (meth)acrylic copolymer having a chain-polymerizable functional group (hereinafter, may be referred to as a “(meth)acrylic copolymer A”), a cross-linking agent, and a photopolymerization initiator.

Examples of the chain-polymerizable functional group include an ethylenically unsaturated group such as a (meth)acryloyl group, a vinyl group, and an allyl group, and the like. The (meth)acrylic copolymer A, first, can be obtained by synthesizing a (meth)acrylic copolymer having at least one type of functional group selected from a hydroxyl group, a glycidyl group (an epoxy group), an amino group, and the like (hereinafter, may be referred to as a “(meth)acrylic copolymer B”), and then, causing a reaction between the (meth)acrylic copolymer B and a compound having a chain-polymerizable functional group (hereinafter, may be referred to as a “functional group-introduced compound”).

The (meth)acrylic copolymer A is not particularly limited insofar as the (meth)acrylic copolymer has a chain-polymerizable functional group and the copolymer itself has adhesiveness. Specific examples of the (meth)acrylic copolymer A include a resin satisfying each of the following conditions.
A glass transition temperature is −40° C. or lower
A hydroxyl value is 20 to 150 mgKOH/g
0.3 to 1.5 mmol/g of a chain-polymerizable functional group is contained
An acid value is not substantially detected
A weight average molecular weight is 300000 or more

The (meth)acrylic copolymer B can be obtained by synthesis using a known method. Examples of a method for manufacturing the (meth)acrylic copolymer B include a solution polymerization method, a suspension polymerization method, an emulsion polymerization method, a bulk polymerization method, a precipitation polymerization method, a gas-phase polymerization method, a plasma polymerization method, a supercritical polymerization method, and the like. In addition, examples of the type of polymerization reaction include a technique such as ATRP or RAFT, in addition to radical polymerization, cationic polymerization, anionic polymerization, living radical polymerization, living cationic polymerization, living anionic polymerization, coordination polymerization, immortal polymerization, and the like. Among them, the radical polymerization using the solution polymerization method is preferable from the viewpoint of ease of compounding that the compounding is enabled by directly using a resin solution obtained by polymerization, in addition to an excellent economic efficiency, a high reaction rate, ease of polymerization control, and the like.

A monomer used when synthesizing the (meth)acrylic copolymer B is not particularly limited insofar as the monomer has one (meth)acryloyl group in one molecule. Examples of such a monomer include aliphatic (meth)acrylate such as methyl (meth)acrylate, ethyl (meth)acrylate, butyl (meth)acrylate, isobutyl (meth)acrylate, tert-butyl (meth)acrylate, butoxyethyl (meth)acrylate, isoamyl (meth)acrylate, hexyl (meth)acrylate, 2-ethyl hexyl (meth)acrylate, heptyl (meth)acrylate, octyl heptyl (meth)acrylate, nonyl (meth)acrylate, decyl (meth)acrylate, undecyl (meth)acrylate, lauryl (meth)acrylate, tridecyl (meth)acrylate, tetradecyl (meth)acrylate, pentadecyl (meth)acrylate, hexadecyl (meth)acrylate, stearyl (meth)acrylate, behenyl (meth)acrylate, methoxypolyethylene glycol (meth)acrylate, ethoxypolyethylene glycol (meth)acrylate, methoxypolypropylene glycol (meth)acrylate, ethoxypolypropylene glycol (meth)acrylate, and mono (2-(meth)acryloyl oxyethyl) succinate; alicyclic (meth)acrylate such as cyclopentyl (meth)acrylate, cyclohexyl (meth)acrylate, cyclopentyl (meth)acrylate, dicyclopentanyl (meth)acrylate, dicyclopentenyl (meth)acrylate, isobornyl (meth)acrylate, mono(2-(meth)acryloyl oxyethyl) tetrahydrophthalate, and mono(2-(meth)acryloyl oxyethyl) hexahydrophthalate; aromatic (meth)acrylate such as benzyl (meth)acrylate, phenyl (meth)acrylate, o-biphenyl (meth)acrylate, 1-naphthyl (meth)acrylate, 2-naphthyl (meth)acrylate, phenoxyethyl (meth)acrylate, p-cumyl phenoxyethyl (meth)acrylate, o-phenyl phenoxyethyl (meth)acrylate, 1-naphthoxyethyl (meth)acrylate, 2-naphthoxyethyl (meth)acrylate, phenoxypolyethylene glycol (meth)acrylate, nonyl phenoxypolyethylene glycol (meth)acrylate, phenoxypolypropylene glycol (meth)acrylate, 2-hydroxy-3-phenoxypropyl (meth)acrylate, 2-hydroxy-3-(o-phenyl phenoxy) propyl (meth)acrylate, 2-hydroxy-3-(1-naphthoxy) propyl (meth)acrylate, and 2-hydroxy-3-(2-naphthoxy) propyl (meth)acrylate; heterocyclic (meth)acrylate such as 2-tetrahydrofurfuryl (meth)acrylate, N-(meth)acryloyl oxyethyl hexahydrophthalimide, and 2-(meth)acryloyl oxyethyl-N-carbazole; a caprolactone-modified product thereof; a compound having an ethylenically unsaturated group and an epoxy group, such as ω-carboxy-polycaprolactone mono(meth)acrylate, glycidyl (meth)acrylate, α-ethyl glycidyl (meth)acrylate, α-propyl glycidyl (meth)acrylate, α-butyl glycidyl (meth)acrylate, 2-methyl glycidyl (meth)acrylate, 2-ethyl glycidyl (meth)acrylate, 2-propyl glycidyl (meth)acrylate, 3,4-epoxy butyl (meth)acrylate, 3,4-epoxy heptyl (meth)acrylate, α-ethyl-6,7-epoxy heptyl (meth)acrylate, 3,4-epoxy cyclohexyl methyl (meth)acrylate, o-vinyl benzyl glycidyl ether, m-vinyl benzyl glycidyl ether, and p-vinyl benzyl glycidyl ether; a compound having an ethylenically unsaturated group and an oxetanyl group, such as (2-ethyl-2-oxetanyl) methyl (meth)acrylate, (2-methyl-2-oxetanyl) methyl (meth)acrylate, 2-(2-ethyl-2-oxetanyl) ethyl (meth)acrylate, 2-(2-methyl-2-oxetanyl) ethyl (meth)acrylate, 3-(2-ethyl-2-oxetanyl) propyl (meth)acrylate, and 3-(2-methyl-2-oxetanyl) propyl (meth)acrylate; a compound having an ethylenically unsaturated group and an isocyanate group, such as 2-(meth)acryloyl oxyethyl isocyanate; a compound having an ethylenically unsaturated group and a hydroxyl group, such as 2-hydroxyethyl (meth)acrylate, 2-hydroxypropyl (meth)acrylate, 4-hydroxybutyl (meth)acrylate, 3-chloro-2-hydroxypropyl (meth)acrylate, and 2-hydroxybutyl (meth)acrylate, and the like.

As the monomer used when synthesizing the (meth)acrylic copolymer B, as necessary, styrene copolymerizable with the monomer described above and a derivative thereof, a maleimide compound such as alkyl maleimide, cycloalkyl maleimide, aryl maleimide, and the like can be used.

The (meth)acrylic copolymer B has one type of functional group selected from a hydroxyl group, a glycidyl group (an epoxy group), an amino group, and the like, as a reaction point with the functional group-introduced compound described below or a reaction point with the cross-linking agent. Such a functional group can be introduced by using one type selected from a compound having an ethylenically unsaturated group and an epoxy group, a compound having an ethylenically unsaturated group and a hydroxyl group, and the like, as the monomer used when synthesizing the (meth)acrylic copolymer B.

In addition, it is preferable to use one type selected from aliphatic (meth)acrylate having an alkyl group with 8 to 23 carbon atoms, as the monomer used when synthesizing the (meth)acrylic copolymer B. Since the (meth)acrylic copolymer B obtained by copolymerizing such a monomer has a low glass transition temperature, there is a tendency that excellent adhesion properties are exhibited.

In order to obtain the (meth)acrylic copolymer B, a known polymerization initiator can be used. Such a polymerization initiator can be used without any particular limitation insofar as the polymerization initiator is a compound generating radicals by heating at 30° C. or higher.

A reaction solvent used during solution polymerization is not particularly limited insofar as the reaction solvent is a solvent (an organic solvent) capable of dissolving the (meth)acrylic copolymer B. Further, it is also possible to perform the polymerization by using supercritical carbon dioxide or the like in the solvent.

The (meth)acrylic copolymer A can be obtained by causing a reaction between the (meth)acrylic copolymer B and the functional group-introduced compound. Examples of the functional group-introduced compound include a compound having an ethylenically unsaturated group and an epoxy group, such as glycidyl (meth)acrylate, α-ethyl glycidyl (meth)acrylate, α-propyl glycidyl (meth)acrylate, α-butyl glycidyl (meth)acrylate, 2-methyl glycidyl (meth)acrylate, 2-ethyl glycidyl (meth)acrylate, 2-propyl glycidyl (meth)acrylate, 3,4-epoxy butyl (meth)acrylate, 3,4-epoxy heptyl (meth)acrylate, α-ethyl-6,7-epoxy heptyl (meth)acrylate, 3,4-epoxy cyclohexyl methyl (meth)acrylate, o-vinyl benzyl glycidyl ether, m-vinyl benzyl glycidyl ether, and p-vinyl benzyl glycidyl ether; a compound having an ethylenically unsaturated group and an oxetanyl group, such as (2-ethyl-2-oxetanyl) methyl (meth)acrylate, (2-methyl-2-oxetanyl) methyl (meth)acrylate, 2-(2-ethyl-2-oxetanyl) ethyl (meth)acrylate, 2-(2-methyl-2-oxetanyl) ethyl (meth)acrylate, 3-(2-ethyl-2-oxetanyl) propyl (meth)acrylate, and 3-(2-methyl-2-oxetanyl) propyl (meth)acrylate; a compound having an ethylenically unsaturated group and an isocyanate group, such as methacryloyl isocyanate, 2-methacryloyl oxyethyl isocyanate, 2-acryloyl oxyethyl isocyanate, and m-isopropenyl-α,α-dimethyl benzyl isocyanate; a compound having an ethylenically unsaturated group and a hydroxyl group, such as 2-hydroxyethyl (meth)acrylate, 2-hydroxypropyl (meth)acrylate, 3-chloro-2-hydroxypropyl (meth)acrylate, and 2-hydroxybutyl (meth)acrylate; a compound having an ethylenically unsaturated group and a carboxyl group, such as a (meth)acrylic acid, a crotonic acid, a cinnamic acid, succinic acid (2-(meth)acryloyl oxyethyl), 2-phthaloyl ethyl (meth)acrylate, 2-tetrahydrophthaloyl ethyl (meth)acrylate, 2-hexahydrophthaloyl ethyl (meth)acrylate, ω-carboxy-polycaprolactone mono(meth)acrylate, a 3-vinyl benzoic acid, and a 4-vinyl benzoic acid, and the like.

Among them, from the viewpoint of a cost and/or reactivity, the functional group-introduced compound may be at least one type selected from the group consisting of 2-(meth)acryloyl oxyethyl isocyanate, glycidyl (meth)acrylate, 3,4-epoxy cyclohexyl methyl (meth)acrylate, isocyanic acid ethyl (meth)acrylate, 2-hydroxyethyl (meth)acrylate, 2-hydroxypropyl (meth)acrylate, 2-hydroxybutyl (meth)acrylate, a (meth)acrylic acid, a crotonic acid, and 2-hexahydrophthaloyl ethyl (meth)acrylate, and is preferably 2-(meth)acryloyl oxyethyl isocyanate.

When causing the reaction between the (meth)acrylic copolymer B and the functional group-introduced compound, as necessary, it is possible to add a catalyst for accelerating an addition reaction or add a polymerization inhibitor in order to avoid the cleavage of a double bond during the reaction.

The (meth)acrylic copolymer A may be a reactant between a (meth)acrylic copolymer having a hydroxyl group as the (meth)acrylic copolymer B and 2-(meth)acryloyl oxyethyl isocyanate as the functional group-introduced compound.

It is preferable that the content of the (meth)acrylic copolymer A in the adhesive layer is greater than 50 parts by mass with respect to 100 parts by mass of the ultraviolet-curable adhesive agent configuring the adhesive layer.

The cross-linking agent, for example, is used to control the storage modulus and/or the adhesiveness of the adhesive layer. The cross-linking agent is not particularly limited insofar as the cross-linking agent is a compound having two or more substituents capable of reacting with at least one type of functional group selected from a hydroxyl group, a glycidyl group (an epoxy group), an amino group, and the like in the (meth)acrylic copolymer A, in one molecule. Examples of a bond formed by a reaction between the (meth)acrylic copolymer A and the cross-linking agent include an ester bond, an ether bond, an amide bond, an imide bond, a urethane bond, a urea bond, and the like.

The cross-linking agent is preferably an isocyanate compound having two or more isocyanate groups. By using such an isocyanate compound, a reaction with a functional group in the (meth)acrylic copolymer A, such as a hydroxyl group, a glycidyl group, and an amino group, easily occurs, a rigid cross-linking structure is formed, and the adhesive layer can be prevented from being brittle after the ultraviolet irradiation.

Examples of the isocyanate compound having two or more isocyanate groups include an isocyanate compound such as 2,4-tolylene diisocyanate, 2,6-tolylene diisocyanate, 1,3-xylylene diisocyanate, 1,4-xylene diisocyanate, diphenyl methane-4,4′-diisocyanate, diphenyl methane-2,4′-diisocyanate, 3-methyl diphenyl methane diisocyanate, hexamethylene diisocyanate, isophorone diisocyanate, dicyclohexyl methane-4,4′-diisocyanate, dicyclohexyl methane-2,4′-diisocyanate, and lysine isocyanate, and the like.

As the cross-linking agent, an isocyanate-containing oligomer obtained by a reaction between the isocyanate compound described above and polyhydric alcohol having two or more hydroxyl groups can also be used. Examples of the polyhydric alcohol used to obtain such an oligomer include ethylene glycol, propylene glycol, butylene glycol, 1,6-hexane diol, 1,8-octane diol, 1,9-nonane diol, 1,10-decane diol, 1,11-undecane diol, 1,12-dodecane diol, glycerine, pentaerythritol, dipentaerythritol, 1,4-cyclohexane diol, 1,3-cyclohexane diol, and the like.

Among them, the cross-linking agent is more preferably a reactant between the isocyanate compound having two or more isocyanate groups and polyhydric alcohol having three or more hydroxyl groups. By using such a reactant (the isocyanate-containing oligomer), the adhesive layer forms a dense cross-linking structure, and the adhesive layer can be prevented from being brittle after the ultraviolet irradiation.

It is preferable that the content of the cross-linking agent in the adhesive layer is 0.05 to 1.5 parts by mass with respect to 100 parts by mass of the (meth)acrylic copolymer A. In a case where the content of the cross-linking agent is 0.05 parts by mass or more with respect to 100 parts by mass of the (meth)acrylic copolymer A, the adhesive layer can be prevented from being brittle after the ultraviolet irradiation. On the other hand, in a case where the content of the cross-linking agent is 1.5 parts by mass or less with respect to 100 parts by mass of the (meth)acrylic copolymer A, there is a tendency that the adhesive force of the adhesive layer before the ultraviolet irradiation can be prevented from being excessively weakened, and there is a tendency that a force for fixing the semiconductor chip is sufficient.

The photopolymerization initiator is not particularly limited insofar as activated species capable of causing chain polymerization in the (meth)acrylic copolymer A can be generated by the irradiation of one or more types of light selected from an ultraviolet ray, an electron beam, and a visible light ray, and for example, may be a radical photopolymerization initiator, or may be a cationic photopolymerization initiator. The activated species capable of causing the chain polymerization is not particularly limited insofar as a polymerization reaction is started by a reaction with the chain-polymerizable functional group of the (meth)acrylic copolymer A described above.

The optimum value of the content of the photopolymerization initiator in the adhesive layer is different in accordance with the target thickness of the adhesive layer and/or a light source to be used, but is preferably 0.5 to 1.5 parts by mass with respect to 100 parts by mass of the (meth)acrylic copolymer A. In a case where the content of the photopolymerization initiator is 0.5 parts by mass or more with respect to 100 parts by mass of the (meth)acrylic copolymer A, a peeling force after the ultraviolet irradiation sufficiently decreases, and there is a tendency that a problem is less likely to occur even in a case where a thrust amount for pickup is low. In a case where the content of the photopolymerization initiator is 1.5 parts by mass or less with respect to 100 parts by mass of the (meth)acrylic copolymer A, it is economically advantageous.

The thickness of the adhesive layer is generally 1 to 100 μm, and is preferably 2 to 50 μm, and more preferably 5 to 40 μm. In a case where the thickness of the adhesive layer is 1 μm or more, it is possible to ensure a sufficient adhesive force to the semiconductor chip, and it is possible to prevent the shattering of the semiconductor chip during the tape expanding step at a higher level. On the other hand, in a case where the thickness of the adhesive layer is 100 μm or less, it is economically advantageous.

In addition, the thickness of the adhesive layer is preferably 10 μm or more, more preferably 20 to 50 μm, and even more preferably 30 to 50 μm. In a case where the thickness of the adhesive layer is 10 μm or more, the base material film is not damaged (notched or the like) even when dicing the semiconductor wafer on the expansion tape without using the dicing tape, and in the preparing step, a step of dicing the semiconductor wafer on the dicing tape to transfer (laminate) the semiconductor chip to the expansion tape can be omitted.

### <Method for Manufacturing Expansion Tape>

The expansion tape can be manufactured in accordance with a well-known technology in the technical field. For example, the expansion tape can be manufactured in accordance with the following method. First, a varnish containing the component and the solvent configuring the adhesive layer is applied to a protective film by a knife coating method, a roll coating method, a spray coating method, a gravure coating method, a bar coating method, a curtain coating method, and the like, and the solvent is removed to form the adhesive layer. A condition for removing the solvent, for example, may be a heating condition at 50 to 200° C. for 0.1 to 90 minutes. It is preferable that the condition for removing the solvent is a condition for removing the solvent until the content is 1.5% by mass or less unless there is an influence on the generation of voids or the adjustment of a viscosity in each step. Next, the expansion tape can be obtained by laminating the prepared protective film with the adhesive layer and the base material film in a temperature condition of 25 to 60° C. such that the adhesive layer and the base material film face each other. In the use of the expansion tape, the expansion tape is used after the protective film is peeled off.

Examples of the protective film include A-63 (manufactured by Toyobo Film Solutions Limited, Mold Release Treatment Agent: modified silicone-based), A-31 (manufactured by Toyobo Film Solutions Limited, Mold Release Treatment Agent: Pt-based silicone-based), and the like.

The thickness of the protective film is suitably selected in a range where the workability is not impaired. The thickness of the protective film may be 100 μm or less from the economic viewpoint. The thickness of the protective film is preferably 10 to 75 μm, and more preferably 25 to 50 μm. In a case where the thickness of the protective film is 10 μm or more, a problem that the film is broken when preparing the expansion tape is less likely to occur. In addition, in a case where the thickness of the protective film is 75 μm or less, the protective film can be easily peeled off when using the expansion tape.

### (Carrier)

The carrier is not particularly limited insofar as the carrier can be resistant to a transfer temperature and a transfer pressure (the chip is not damaged, and the chip interval is not changed), and can also be resistant to a sealing temperature and a sealing pressure. For example, in a case where the sealing temperature is 100 to 200° C., it is preferable that the carrier has heat resistance that can be resistant to such a temperature region. In addition, a thermal expansion rate is preferably 100 ppm/° C. or lower, more preferably 50 ppm/° C. or lower, and even more preferably 20 ppm/° C. or lower. In a case where the thermal expansion rate is high, there is a tendency that a problem such as the position aberration of the semiconductor chip is likely to occur. In addition, since strain or warpage occurs when the thermal expansion rate is lower than that of the semiconductor chip, it is preferable that the thermal expansion rate is 3 ppm/° C. or higher.

The material of the carrier is not particularly limited, and examples thereof include a plate such as silicon (a wafer), glass, SUS, iron, and Cu, a glass epoxy substrate, and the like.

The thickness of the carrier may be 100 to 5000 μm, and is preferably 100 to 4000 μm, and more preferably 100 to 3000 μm. In a case where the thickness of the carrier is 100 μm or more, there is a tendency that the handleability is improved. Since it is not expected to significantly improve the handleability even when the carrier is thick, the thickness of the carrier may be 5000 μm or less in consideration of an economic aspect.

The carrier may be composed of a plurality of layers. In the carrier, from the viewpoint of imparting the control of an adhesion force, a layer to which adhesiveness is imparted or a layer in which a temporary fixing material is laminated may be provided, in addition to a layer to which the heat resistance and the handleability are imparted. Such a layer can be arbitrarily provided in consideration of the adhesion force of the semiconductor chip or the expansion tape. In a case where the carrier is composed of the plurality of layers, the thickness of the carrier is not particularly limited, and for example, may be 1 to 300 μm, and is preferably 1 to 200 μm. In a case where the thickness is 1 μm or more, it is possible to ensure a sufficient adhesive force to the semiconductor chip. On the other hand, in a case where the thickness is greater than 300 μm, there is no advantage in properties, which is uneconomical.

### EXAMPLES

Hereinafter, the present invention will be described in more detail by using Examples, but the present invention is not limited thereto.

### <Preparation of Solution of (Meth)Acrylic Copolymer>

1000 g of ethyl acetate, 650 g of 2-ethyl hexyl acrylate, 350 g of 2-hydroxyethyl acrylate, and 3.0 g of azobisisobutyronitrile were compounded in an autoclave having a capacity of 4000 mL in which a three-one motor, a stirring blade, and a nitrogen introduction tube were provided, and stirred to be even, and then, nitrogen bubbling was implemented at a flow rate of 100 ml/minute for 60 minutes to deaerate dissolved oxygen in the system. The temperature was increased to 60° C. for 1 hour, and polymerization was performed for 4 hours after the temperature was increased. After that, the temperature was increased to 90° C. for 1 hour, retained at 90° C. for 1 hour, and then, cooled to the room temperature. Next, 1000 g of ethyl acetate was added, stirred, and diluted. 0.1 g of methoquinone as a polymerization inhibitor and 0.05 g of dioctyl tin dilaurate as a urethanization catalyst were added thereto, and then, 100 g of 2-methacryloyl oxyethyl isocyanate (manufactured by Showa Denko K.K., Karenz MOI (Registered Trademark)) was added. A reaction was performed at 70° C. for 6 hours, and then, cooled to the room temperature. After that, ethyl acetate was added to adjust a non-volatile content in a solution of a (meth)acrylic copolymer to 35% by mass, and a solution of a (meth)acrylic copolymer having a chain-polymerizable functional group was obtained.

As a result of measuring the acid value and the hydroxyl value of the (meth)acrylic copolymer in accordance with JIS K0070, the acid value was not detected, and the hydroxyl value was 121 mgKOH/g. In addition, the obtained solution of the (meth)acrylic copolymer was vacuum-dried at 60° C. overnight, and the obtained solid content was subjected to element analysis with a full automatic element analyzer (manufactured by Elementar Analysensysteme GmbH, varioEL). As a result of calculating the content of 2-methacryloxyethyl isocyanate introduced to the (meth)acrylic copolymer from the measured nitrogen content, the content was 0.59 mmol/g. In addition, as a result of GPC measurement using SD-8022/DP-8020/RI-8020 (manufactured by Tosoh Corporation), using Gelpack GL-A150-S/GL-A160-S (manufactured by Hitachi Chemical Company, Ltd.) as a column, and using tetrahydrofuran as an eluent, the weight average molecular weight in terms of polystyrene was 420000.

### <Preparation of Base Material Film>

As a base material film, a resin film was used in which Himilan 1706 (manufactured by Dupont-Mitsui Polychemicals Co., Ltd., an ionomer resin), an ethylene/1-hexene copolymer and a butene/α-olefin copolymer, and Himilan 1706 were laminated in this order. In the thickness of each layer, Himilan 1706: Ethylene/1-Hexene Copolymer and Butene/α-Olefin Copolymer:Himilan 1706 was 1:2:1.

### <Tensile Test in MD Direction and TD Direction of Base Material Film (Expansion Tape)>

A tensile test in an MD direction and a TD direction was performed with respect to the base material film to obtain a stress-strain curve. In the tensile test in the MD direction and the TD direction of the base material film, an autograph (AG-Xplus, manufactured by SHIMADZU CORPORATION) was used. The base material film was cut out to have a width of 20 mm and a length of 50 mm in each of the MD direction and the TD direction, and evaluation samples for performing the tensile test in the MID direction and the TD direction were set. Such evaluation samples were used and stretched from 0% to 400% at a distance between chucks of 50 mm and a tensile rate of 1 mm/s to perform the tensile test, and the stress-strain curve was obtained. Note that, the measurement was performed with a high-temperature test device (TCLN type, manufactured by SHIMADZU CORPORATION) at 50° C. that is a stage temperature when expanding an expansion tape.

A tensile test in an MD direction and a TD direction of an expansion tape greatly depends on the properties of the base material film. Therefore, the stress-strain curve obtained by the tensile test in the MI direction and the TD direction of the base material film was regarded as a stress-strain curve obtained by a tensile test in an MD direction and a TD direction of an expansion tape of Manufacturing Example 1 described below.

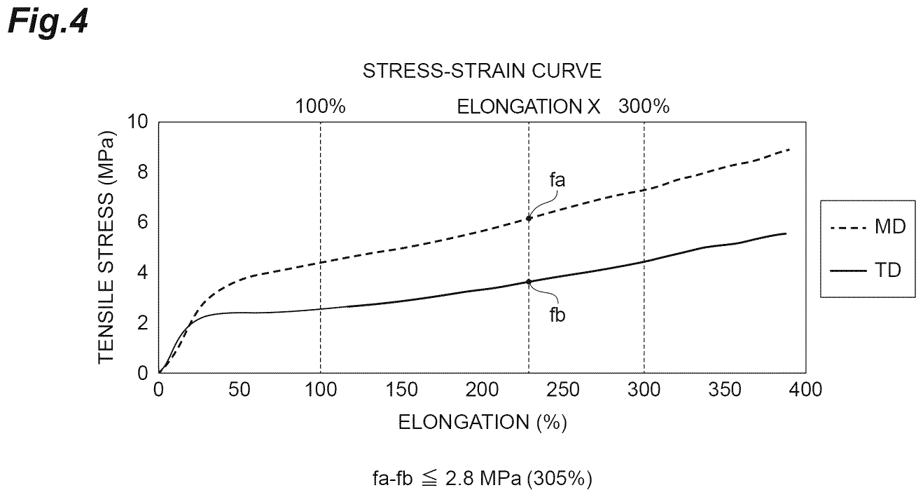

FIG. 4 is a graph of the stress-strain curve obtained by the tensile test in the MD direction and the TD direction of the base material film (the expansion tape of Manufacturing Example 1). The range of extension X in which an absolute value of a difference between fa and fb was 2.8 MPa or less, which was obtained from the graph illustrated in FIG. 4, was greater than 0% and 305% or less, and overlapped with the entire range of greater than 100% and less than 300%. Accordingly, in the case of using an expansion tape having the base material film described above, it was determined that it was suitable to select an expansion rate per one expansion in a tape expanding step from the range of greater than 100% and less than 300%.

### Manufacturing Example 1

### <Preparation of Expansion Tape>

0.2 parts by mass, as a solid content, of polyfunctional isocyanate (manufactured by Nippon Polyurethane Industry Co., Ltd., CORONATE L, a solid content of 75%) as a cross-linking agent, 1.0 part by mass of 1-hydroxycyclohexyl phenyl ketone (manufactured by BASF, Irgacure 184) as a photopolymerization initiator, and 2-butanone were added to the acrylic resin solution (Solid Content: 100 parts by mass) described above such that the total solid content was 25% by mass, and evenly stirred for 10 minutes. After that, the obtained solution was applied onto a protective film (polyethylene terephthalate of which the surface was subjected to a mold release treatment, a thickness of 25 μm) and dried to form an adhesive layer. In this case, the thickness of the adhesive layer when dried was 10 μm. Next, the base material film was prepared, and the surface of the adhesive layer was laminated on the base material film, and the obtained tape was aged at 40° C. for 4 days. As described above, the expansion tape of Manufacturing Example 1 was obtained.

Note that, the adhesive layer, the protective film, and the base material film were laminated with a roll laminator at 40° C. to have a configuration in the order of Protective Film/Adhesive Layer/Base Material Film. Such a laminated body was used by peeling off the protective film when used as the expansion tape.

### Example 1

### <Preparation of Semiconductor Chip (Step 1)>

5 cm square of a silicon wafer (a thickness of 200 μm) was laminated with a hand roller on a dicing tape (UPH-1005M3, manufactured by Denka Company Limited) pasted to a 12-inch dicing ring on a hot plate at 40° C., and diced with a blade to have a size of 0.25 mm×0.25 mm by using a dicing device (DFD3360, manufactured by DISCO Corporation), and a plurality of singulated semiconductor chips were obtained. After that, 365 mJ of an ultraviolet ray (UV) was applied with a UV-exposure device (ML-320FSAT, manufactured by Mikasa Co., Ltd.) to decrease the adhesion force of the dicing tape.

### <Transfer of Semiconductor Chip to Expansion Tape (Step 2)>

The plurality of semiconductor chips were transferred with a hand roller to the adhesive layer of the expansion tape of Manufacturing Example 1 pasted to an 8-inch dicing ring on a hot plate at 40° C. After the transferring, the dicing tape was peeled off, and a laminated body (an expansion sample 1) including the expansion tape and the plurality of semiconductor chips fixed onto the expansion tape was obtained. Next, each 8-inch dicing ring was set in an 8-inch expander device (manufactured by OHMIYA IND. CO., LTD., MX-5154FN). In this case, the initial interval between the semiconductor chips was 45 μm.

### <Tape Expanding Step and Tension Retaining Step (Step 3)>

Subsequently, the expansion tape was thrust to a suitable height and stretched such that the interval between the semiconductor chips was expanded from 45 μm to 100 μm (Expansion Rate: 222% (=100/45×100)) at a thrust rate of 1 mm/second and a temperature (a stage temperature) of 50° C. The sample obtained by expanding the expansion tape was fixed with a 6-inch dicing ring to retain the tension, and a transfer sample 1 was set.

### <Tape Expanding Step and Tension Retaining Step (Repeating Step 1) (Step 4)>

The transfer sample 1 was irradiated with 600 mJ of an ultraviolet ray (UV) by using a UV-exposure device (ML-320FSAT, manufactured by Mikasa Co., Ltd.) to decrease the adhesion force of the expansion tape. Next, another expansion tape of Manufacturing Example 1 was prepared, and the plurality of semiconductor chips were transferred with a hand roller to the adhesive layer of the expansion tape of Manufacturing Example 1 pasted to an 8-inch dicing ring on a hot plate at 40° C. After the transferring, the expansion tape used in the transfer sample 1 was peeled off, and a laminated body (an expansion sample 2) including the expansion tape and the plurality of semiconductor chips fixed onto the expansion tape was obtained.

Subsequently, the expansion tape was thrust to a suitable height and stretched such that the interval between the semiconductor chips was expanded from 100 μm to 150 μm (Expansion Rate: 150% (=150/100×100)) at a thrust rate of 1 mm/second and a temperature (a stage temperature) of 50° C. The expansion sample 2 obtained by expanding the expansion tape was fixed with a 6-inch dicing ring to retain the tension, and a transfer sample 2 was set.

### <Tape Expanding Step and Tension Retaining Step (Repeating Step 2) (Step 5)>

The step 4 was repeated such that the interval between the semiconductor chips was expanded from 150 μm to 200 μm (Expansion Rate: 133% (=200/150×100)), from 200 μm to 250 μm (Expansion Rate: 125% (=250/200×100)), and from 250 μm to 300 μm (Expansion Rate: 120% (=300/250×100)) to be finally 300 μm, the expansion sample obtained by expanding the expansion tape was fixed with a 6-inch dicing ring to retain the tension, and a position aberration measurement sample of Example 1 was obtained.

### Example 2

A position aberration measurement sample of Example 2 was obtained as with Example 1, except that the step 5 was not performed. Note that, in the step 3, the expansion tape was thrust to a suitable height and stretched such that the interval between the semiconductor chips was expanded from 45 μm to 127.5 μm (Expansion Rate: 283% (=127.5/45×100)) at a thrust rate of 1 mm/second and a temperature (a stage temperature) of 50° C. In addition, in the step 4, the expansion tape was thrust to a suitable height and stretched such that the interval between the semiconductor chips was expanded from 127.5 μm to 300 μm (Expansion Rate: 235% (=300/127.5×100)) at a thrust rate of 1 mm/second and a temperature (a stage temperature) of 50° C. The sample obtained by expanding the expansion tape was fixed with a 6-inch dicing ring to retain the tension, and the position aberration measurement sample of Example 2 was set.

### Comparative Example 1

A position aberration measurement sample of Comparative Example 1 was obtained as with Example 1, except that the step 4 and the subsequent steps were not performed. Note that, in the step 3, the expansion tape was thrust to a suitable height and stretched such that the interval between the semiconductor chips was expanded from 45 μm to 300 μm (Expansion Rate: 666% (=300/45×100)) at a thrust rate of 1 mm/second and a temperature (a stage temperature) of 50° C. The sample obtained by expanding the expansion tape was fixed with a 6-inch dicing ring to retain the tension, and the position aberration measurement sample of Comparative Example 1 was set.

### <Evaluation of Position Aberration During Final Expansion>

The coordinate position of the semiconductor chip after the step 1 described above (before the expanding) was measured with NEXIV VM7-K (manufactured by Nikon Instech Co., Ltd.). Next, the coordinate position of the semiconductor chip after the expanding was measured by using the position aberration measurement samples of Example 1, Example 2, and Comparative Example 1. In this case, as a measurement point, a total of 37 points including 1 point at the center and 36 points at the periphery (5 points each on the top, bottom, left, and right based on the center, and 4 points each in an oblique direction) were measured. On the basis of a measurement result of the coordinate position of the semiconductor chip after the step 1 described above (before the expanding), the assumed ideal coordinate position of the semiconductor chip when expanded until the interval between the semiconductor chips was 300 μm was determined. Next, a difference between the ideal coordinate position after the expanding and the actual coordinate position after the expanding was obtained, and the average value of the difference was set as the position aberration. It can be said that the position aberration increases as the average value of the difference between the ideal coordinate position after the expanding and the actual coordinate position after the expanding increases. Results are shown in Table 1.

TABLE 1

| | Number of times | | | Position |
|---|---|---|---|---|
| | of tape expanding | | | aberration at final |
| | step (times) | Expansion rate (%) | | expansion (μm) |
| Exam. 1 | 5 | First time | 222 | 88 |
| | | Second time | 150 | |
| | | Third time | 133 | |
| | | Fourth time | 125 | |
| | | Fifth time | 120 | |
| Exam. 2 | 2 | First time | 283 | 216 |
| | | Second time | 235 | |
| Comp. | 1 | First time | 666 | 477 |
| Exam. 1 | | | | |

As shown in Table 1, in the position aberration measurement samples of Examples 1 and 2 in which using the predetermined expansion tape to select the expansion rate per one expansion from the properties of the predetermined expansion tape, expanding the interval between the plurality of semiconductor chips on the basis of the selected expansion rate, and repeating the tape expanding step and the transferring step in this order were implemented, the position aberration was small, compared to the position aberration measurement sample of Comparative Example 1 in which such steps were not implemented. From such results, it was checked that in the method for manufacturing a semiconductor device of the present disclosure, the position aberration of the semiconductor chip was sufficiently suppressed when expanding the interval between the singulated semiconductor chips.

### REFERENCE SIGNS LIST

1: expansion tape, 1a: adhesive layer, 1b: base material film, 2: semiconductor chip, 3: pad (circuit), 4: fixing jig, 5: carrier, 10, 20, 30: laminated body, 40: semiconductor device.

1. A method for manufacturing a semiconductor device comprising a semiconductor chip, the method comprising:
a tape expanding step of stretching a transferring expansion tape while heating to expand an interval between a plurality of semiconductor chips fixed onto the transferring expansion tape at an expansion rate in a range of greater than 100% and less than 300% per one expansion;
a transferring step of transferring the plurality of semiconductor chips to a transferred expansion tape such that a surface of the semiconductor chip on a side opposite to a surface fixed onto the transferring expansion tape is fixed; and
repeating the tape expanding step and the transferring step by using the transferred expansion tape to which the plurality of semiconductor chips are transferred as the transferring expansion tape,
wherein in a stress-strain curve obtained by a tensile test in an MD direction and a TD direction under a heating temperature in the tape expanding of the transferring expansion tape and the transferred expansion tape, when a tensile stress in the MD direction and a tensile stress in the TD direction are set as fa (MPa) and fb (MPa), respectively, an elongation range in which an absolute value of a difference between fa and fb is 2.8 MPa or less overlaps with at least a part of the range of greater than 100% and less than 300%, and
the tape expanding is expanding the interval between the plurality of semiconductor chips by using an elongation value selected from the elongation range of greater than 100% and less than 300%, in which the absolute value of the difference between fa and fb is 2.8 MPa or less, as the expansion rate per one expansion.

2. The method for manufacturing a semiconductor device according to claim 1, further comprising a carrier transferring step of transferring the plurality of semiconductor chips to a carrier.

3. The method for manufacturing a semiconductor device according to claim 1, wherein a size of the semiconductor chip is 25 mm² or less.

4. The method for manufacturing a semiconductor device according to claim 1, wherein a heating temperature during the tape expanding step is 30 to 100° C.

5. The method for manufacturing a semiconductor device according to claim 1, wherein the expansion rate is in a range of 105% or more and 295% or less per one expansion.

6. The method for manufacturing a semiconductor device according to claim 1, wherein the expansion rate is in a range of 110% or more and 290% or less per one expansion.

7. The method for manufacturing a semiconductor device according to claim 1, wherein the tape expanding step and the transferring step are repeated a total of 3 or more times.
